(19) United States
(12) Patent Application Publication
(10) Pub. No.: US 2015/0099358 A1
(43) Pub. Date: Apr. 9, 2015

(54) METHOD FOR FORMING THROUGH WAFER VIAS IN SEMICONDUCTOR DEVICES

(71) Applicant: WIN Semiconductors Corp., Tao Yuan Shien (TW)

(72) Inventors: Chia-Hao CHEN, Tao Yuan Shien (TW); Yu-Wei CHANG, Tao Yuan Shien (TW); Yi-Feng WEI, Tao Yuan Shien (TW); I-Te CHO, Tao Yuan Shien (TW); Walter Tony WOHLMUTH, Tao Yuan Shien (TW)

(73) Assignee: WIN Semiconductors Corp., Tao Yuan Shien (TW)

(21) Appl. No.: 14/047,863

(22) Filed: Oct. 7, 2013

(51) Int. Cl. H01L 21/768; H01L 21/308

(52) U.S. Cl. CPC H01L 21/76802; H01L 21/76822; H01L 21/3081
USPC 438/667

(57) ABSTRACT

A method for forming a through wafer via hole in a semiconductor device, wherein the semiconductor device comprises a wafer having a SiC substrate with a front side and a backside, a GaN-based layer formed on the front side of the SiC substrate, and a mask structure formed on the backside of the SiC substrate defining an etching area. The etching area is first descummed A through substrate via hole is formed by etching the etching area through the SiC substrate. The mask structure is removed and the inner surface of the through substrate via hole is cleaned. The inner surface of the through substrate via hole is then descummed A through wafer via hole is formed by etching through the GaN layer in the through substrate via hole. And lastly the inner surface of the through wafer via hole is cleaned.

### FIELD OF THE INVENTION

The present invention relates to a method for forming a through wafer via hole in a semiconductor device, and more particular to a method for forming a through wafer via hole in a GaN-based semiconductor device on a SiC substrate.

### BACKGROUND OF THE INVENTION

The III-V compound semiconductor material gallium nitride (GaN) has wide bandgap and high breakdown voltage, making it a favorable material for high temperature and high power application. GaN-based semiconductor has been used in the fabrication of light emitting devices, such as blue LEDs and violet laser diodes. Recently, GaN-based semiconductor has also been applied to the fabrication of high-power and high-frequency devices, such as GaN HEMT. The high electron mobility and low energy consumption of GaN transistors make them ideal candidates for making RF switches and power amplifiers.

Silicon carbide (SiC) is chemically stable and does not absorb visible light. It has superior electrical and thermal conductivities, which makes it an ideal candidate for high power and high temperature applications. A GaN-based semiconductor device fabricated on a SiC substrate (GaN/SiC) can be used in an environment which requires high heat and high radiation tolerance, such as various military and space applications like military radar, satellite, space telescopes, etc.

However, the high hardness of the GaN/SiC material makes it difficult for mechanical processing, such as grinding and etching in the wafer backside process. Due to the high hardness of SiC and GaN, the typical etch rate of the backside etching process of a GaN/SiC wafer is very low. Moreover, the inherent defects in the epitaxial growth of the wafer and the byproduct produced during the etching process may cause rough surface morphology of the through via side-wall. The rough surface profile of the through via results in poor metal coverage in the subsequent backside metallization, which usually leads to yield and reliability issues.

### SUMMARY OF THE INVENTION

The main objective of the present invention is to provide an etching method for forming a through wafer via hole in a GaN-based semiconductor device on a SiC substrate, so as to provide an improved via hole side-wall profile with smooth surface morphologies and minimal micromasking.

Another objective of the present invention is to provide an etching method for forming a through wafer via hole in a GaN-based semiconductor device on a SiC substrate of a higher etch rate, so that the throughput can be increased.

To reach the objective stated above, the present invention provides a method for forming a through wafer via hole in a semiconductor device, which comprises steps of:

A1. providing a wafer having a SiC substrate with a front side and a backside and a GaN-based layer formed on the front side of the SiC substrate;

A2. providing a mask structure on the backside of the SiC substrate to define an etching area;

A3. descumming the etching area defined by the mask structure;

A4. forming a through wafer via hole by etching through the SiC substrate and the GaN-based layer in the etching area;

A5. removing the mask structure and cleaning the backside of the SiC substrate and the inner surface of the through wafer via hole.

Moreover, the present invention provides another method for forming a through wafer via hole in a semiconductor device, which comprises steps of:

B1. providing a wafer having a SiC substrate with a front side and a backside and a GaN-based layer formed on the front side of the SiC substrate;

B2. providing a mask structure on the backside of the SiC substrate to define an etching area;

B3. descumming the etching area defined by the mask structure;

B4. forming a through substrate via hole by etching the etching area through the SiC substrate to the GaN layer or partially through the GaN layer;

B5. removing the mask structure and cleaning the backside of the SiC substrate and the inner surface of the through substrate via hole;

B6. descumming the inner surface of the through substrate via hole;

B7. forming a through wafer via hole by etching through the GaN layer in the through substrate via hole;

B8. cleaning the inner surface of the through wafer via hole.

In implementation, the mask structure described above includes at least one mask layer, each of which is made of Si, SiN, Al, Ni, Ni—P, Ti, TiW, or Au.

In implementation, the mask structure described above includes at least one seed layer and at least one metal mask layer formed on the seed layer.

In implementation, each of the at least one seed layer described above is made of Ti, TiW, or Au, and each of the at least one metal mask layer described above is made of Al, Ni, or Ni—P.

In implementation, descumming the etching area in step A3 described above is done by using a plasma comprising one or more of Ar, CF₄, and O₂.

In implementation, etching the etching area through the SiC substrate and the GaN-based layer in step A4 described above is done by using high power fluorine-based plasma, chlorine-based plasma, or fluorine-based and chlorine-based plasma.

In implementation, removing the mask structure and cleaning the backside of the SiC substrate and the inner surface of the through wafer via hole in step A5 described above is done by using an acidic solution with ultrasonic or acoustic vibrations.

In implementation, descumming the etching area in step B3 described above is done by using a plasma comprising one or more of Ar, CF₄, and O₂.

In implementation, etching the etching area in step B4 described above is done by using high power fluorine-based plasma.

In implementation, removing the mask structure and cleaning the backside of the SiC substrate and the inner surface of the through wafer via hole in step B5 described above is done by using an acidic solution with ultrasonic or acoustic vibrations.

In implementation, descumming the inner surface of the through substrate via hole in step B6 described above is done by using plasma of Ar.

In implementation, etching through the GaN layer in step B7 described above is done by using chlorine-based plasma.

In implementation, the chlorine-based plasma described above comprises Cl₂, Ar, and He.

In implementation, the acidic solution described above is a HNO₃ solution, a HCl solution, or a mixed acid consisting of HNO₃ and HCl solution.

In implementation, the mixed acid described above is made of HNO₃, HCl, and de-ionized water in a proportion of 1:1:5.

In implementation, the GaN-based layer described above comprises at least one epitaxial layer, each of which is made of GaN, AlGaN, MN, or InGaN.

The present invention will be understood more fully by reference to the detailed description of the drawings and the preferred embodiments below.

### BRIEF DESCRIPTION OF DRAWINGS

FIG. 1A-1C are cross-sectional views of an embodiment of a method for forming a through wafer via hole in a semiconductor device provided by the present invention.

FIG. 2 is a flow chart of an embodiment of the method for forming a through wafer via hole in a semiconductor device provided by the present invention.

FIG. 3A-3E are cross-sectional views of another embodiment of a method for forming a through wafer via hole in a semiconductor device provided by the present invention.

FIG. 4 is a flow chart of another embodiment of the method for forming a through wafer via hole in a semiconductor device provided by the present invention.

FIG. 5A is a cross-sectional view of an embodiment of the semiconductor device provided by the present invention.

FIG. 5B and 5C are cross-sectional views of embodiments of the mask structure and the GaN-based layer in circle A and circle B respectively in FIG. 5A.

### DETAILED DESCRIPTIONS OF PREFERRED EMBODIMENTS

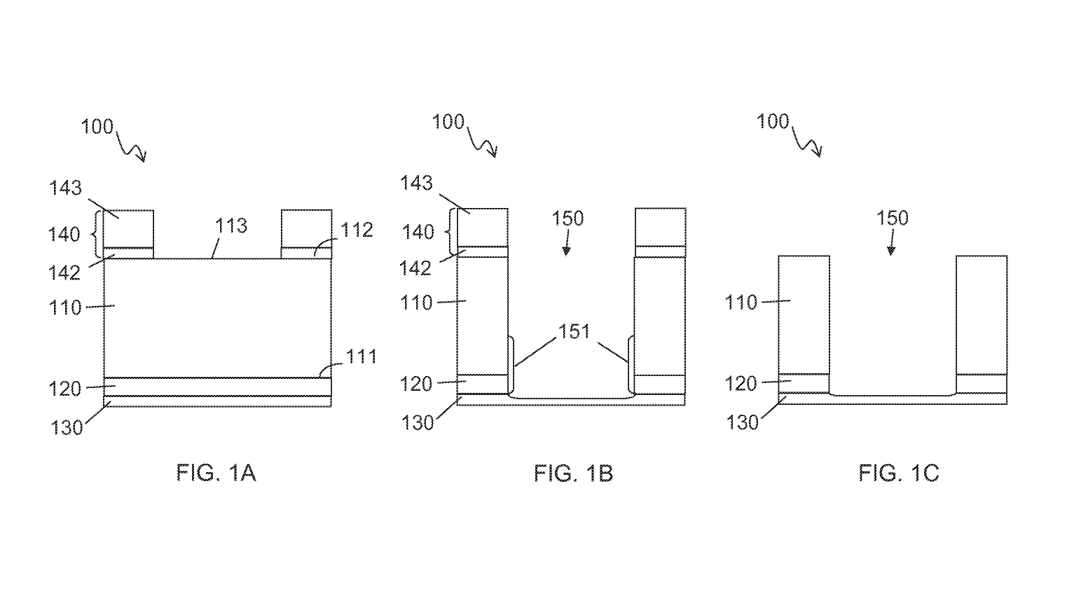

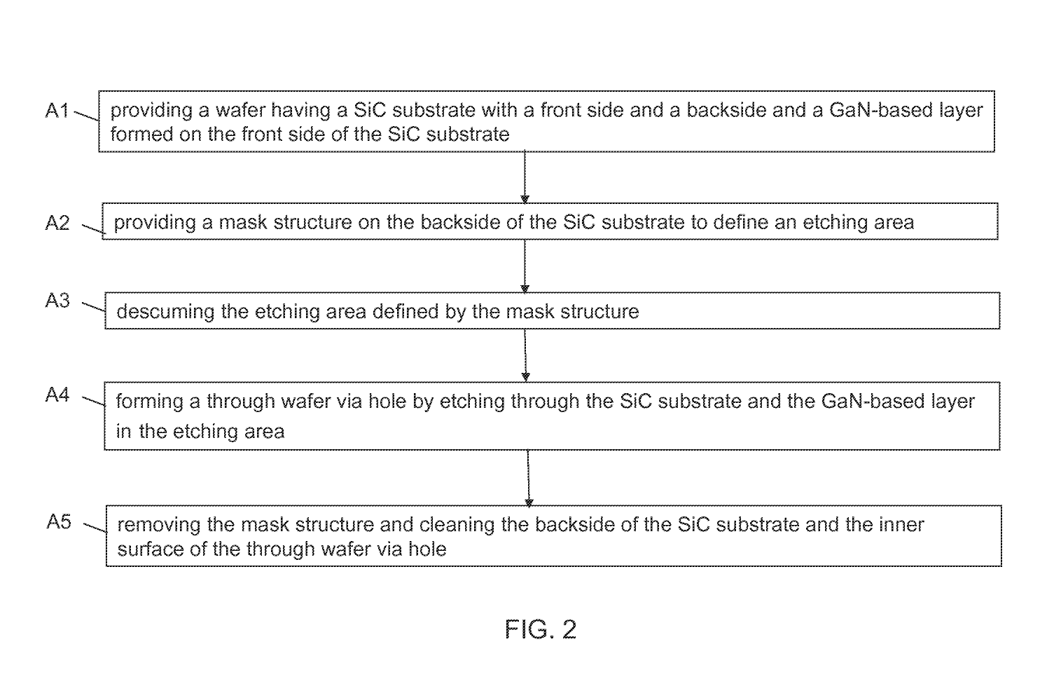

FIG. 1A-1C show an embodiment of a method for forming a through wafer via hole in a semiconductor device provided by the present invention. The method is as shown in the flow chart of FIG. 2, which comprises steps of:

A1. providing a wafer 100 having a SiC substrate 110 with a front side 111 and a backside 112 and a GaN-based layer 120 formed on the front side 111 of the SiC substrate 110;

A2. providing a mask structure 140 on the backside 112 of the SiC substrate 110 to define an etching area 113;

A3. descumming the etching area 113 defined by the mask structure 140;

A4. forming a through wafer via hole 150 by etching through the SiC substrate 110 and the GaN-based layer 120 in the etching area 113;

A5. removing the mask structure 140 and cleaning the backside 112 of the SiC substrate 110 and the inner surface of the through wafer via hole 150.

On the front side of the GaN-based layer 120, an etch stop layer 130 is provided to prevent damage to the electronic device on the front side of the wafer during the wafer backside etching. The method described above includes a one-stage etching process for forming a through wafer via hole in a semiconductor device, which includes descumming the etching area (step A3), etching the etching area (step A4), and cleaning the through wafer via hole (step A5). To reduce the size of the semiconductor device and to save the working time of the backside processing, the backside 112 of the SiC substrate 110 is first ground to reduce the thickness of the SiC substrate. The descum process is used to remove surface defects caused by the SiC substrate 110 grinding process. In the step of descumming the etching area 113 in step A3, plasma comprising one or more of Ar, CF₄, and O₂ is used, preferably uses a mixed gas comprising Ar. After descumming, the through wafer via hole 150 is formed by etching through the SiC substrate 110 and the GaN-based layer 120 in the etching area 113 defined by the mask structure 130 on the backside 112 of the SiC substrate 110. To etch through the high-hardness SiC substrate and the GaN-based layer, high power fluorine-based plasma, chlorine-based plasma, or fluorine-based and chlorine-based plasma is used for etching the etching area 113 in step A4. After the through wafer via hole 150 is formed, the mask structure 140 is removed. The byproduct produced by the high ion bombardment in the etching process is a serious issue. The redeposition of nonvolatile byproducts 151 on the inner surface of the through wafer via hole 150 will cause deficiency in the follow-up backside metallization. The step of removing the mask structure 140 and cleaning the backside 112 of the SiC substrate 110 and the inner surface of the through wafer via hole 150 in step A5 is done by using an acidic solution with ultrasonic or acoustic vibrations. The acidic solution can be a HNO₃ solution, a HCl solution, or a mixed acid consisting of HNO₃ and HCl solution. The preferable acidic solution in the embodiment is a mixed acid made of HNO₃, HCl, and de-ionized water in a proportion about 1:1:5. The surface defectivity caused by the byproduct can be reduced to less than 1% after using the abovementioned mixed acid with ultrasonic vibration.

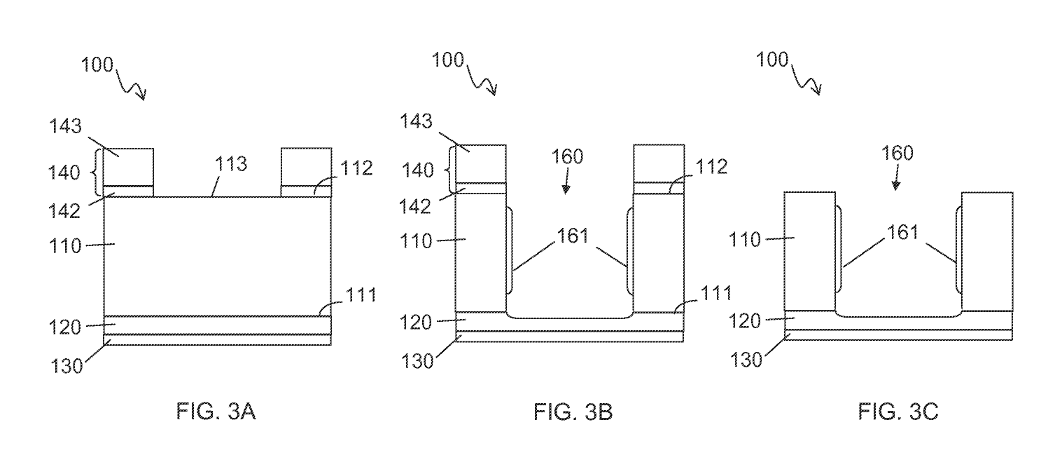

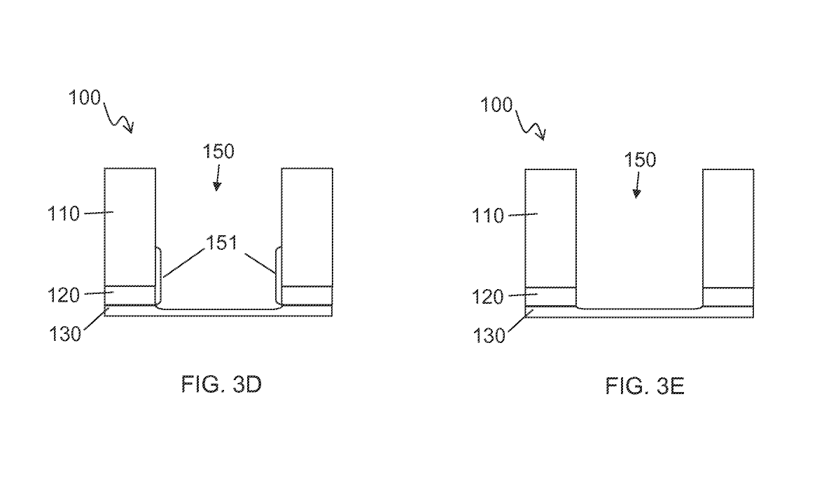

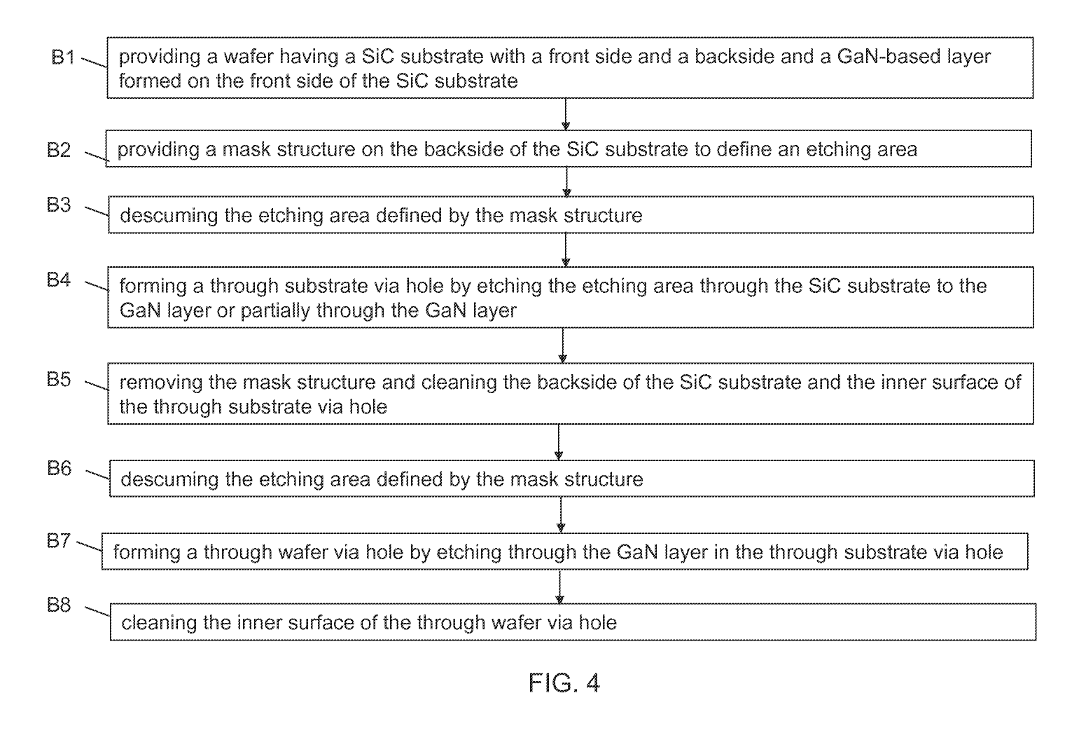

Considering that the hardness of the GaN-based layer and the SiC substrate are different, the optimized etching recipes for the GaN-based layer and the SiC substrate may also be different. To further improve the yield of the through wafer via hole and the backside metallization, the present invention provides a two-stage etching process for forming the through wafer via hole. FIG. 3A-3E show an embodiment of the two-stage etching process provided by the present invention. The method is as described in the flow chart shown in FIG. 4, which comprises steps of:

B1. providing a wafer 100 having a SiC substrate 110 with a front side 111 and a backside 112 and a GaN-based layer 120 formed on the front side 111 of the SiC substrate 110;

B2. providing a mask structure 140 on the backside 112 of the SiC substrate 110 to define an etching area 113;

B3. descumming the etching area 113 defined by the mask structure 140;

B4. forming a through substrate via hole 160 by etching the etching area 113 through the SiC substrate 110 to the GaN layer 120 or partially through the GaN layer 120;

B5. removing the mask structure 140 and cleaning the backside 112 of the SiC substrate 110 and the inner surface of the through substrate via hole 160;

B6. descumming the inner surface of the through substrate via hole;

B7. forming a through wafer via hole 150 by etching through the GaN layer 120 in the through substrate via hole 160;

B8. cleaning the inner surface of the through wafer via hole 150.

The embodiment of the two-stage etching process described above is a repeat of the one-stage etching and applied to the SiC substrate and the GaN-based layer separately. The step of descumming the etching area 113 in step B3 in the embodiment is done by using plasma comprising one or more of Ar, CF₄, and O₂, preferably a mixed gas comprising Ar. After descumming the backside of the SiC substrate, the through substrate via hole 160 is formed by etching the etching area 113 defined by the mask structure 140 on the backside 112 of the SiC substrate 110. To etch through the high-hardness SiC substrate, the step of etching the etching area 113 in step B4 can be done by using high power fluorine-based plasma. After the through substrate via hole 160 is formed, the mask structure 140 is removed, and the byproduct 161 produced by etching SiC substrate is cleaned. The step of removing the mask structure 140 and cleaning the backside 112 of the SiC substrate 110 and the inner surface of the through substrate via hole 160 in step B5 can be done by using an acidic solution with ultrasonic or acoustic vibrations. The acidic solution can be a HNO₃ solution, a HCl solution, or a mixed acid consisting of HNO₃ and HCl solution. A preferable acidic solution in the embodiment is a mixed acid made of HNO₃, HCl, and de-ionized water in a proportion about 1:1:5. The surface particle and inherent defects in expitaxially grown GaN-based layer may induce micromasking effect to on the inner surface of the through substrate via hole 160, which leads to rough surface. In order to reduce the micromasking, a descum process is applied to the inner surface of the through substrate via hole 160 to remove the surface defects before etching the GaN-based layer. The process of descumming the inner surface of the through substrate via hole 160 in step B6 is done by using a plasma of Ar preferably. The etching process of the second stage is optimized for the GaN-based layer. The step of etching through the GaN layer 120 in step B7 can be done by using chlorine-based plasma comprising a mixed gas of Cl₂, Ar, and He.

The cleaning of the inner surface of the through wafer via hole 150 is cleaned in step B8 is done by using an acidic solution with ultrasonic or acoustic vibrations, so as to remove the byproduct 151 produced in the etching process of the GaN-based layer. The acidic solution used in the embodiment can be a HNO₃ solution, a HCl solution, or a mixed acid consisting of HNO₃ and HCl solution. The preferable acidic solution in the embodiment is a mixed acid made of HNO₃, HCl, and de-ionized water in a proportion about 1:1:5. The surface defectivity caused by the byproduct can be reduced to less than 1% after using the abovementioned mixed acid with ultrasonic vibration.

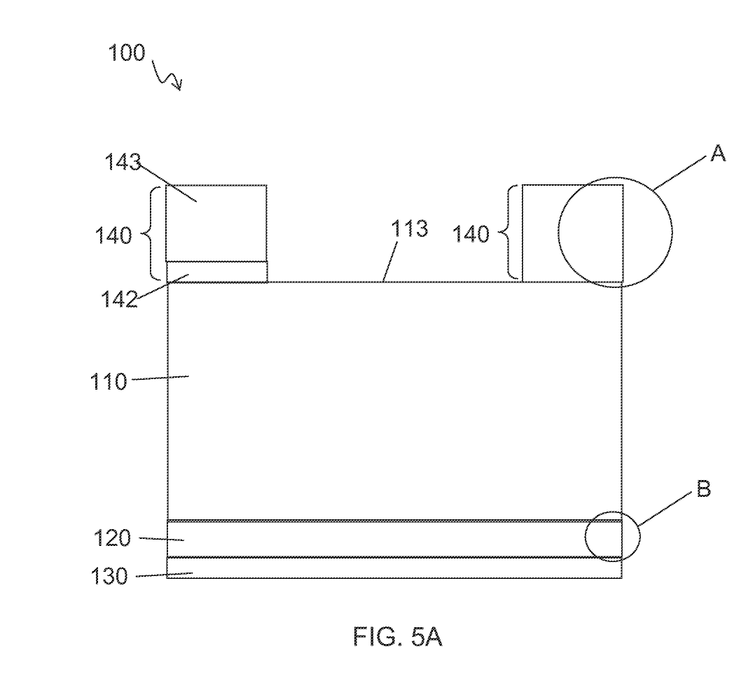

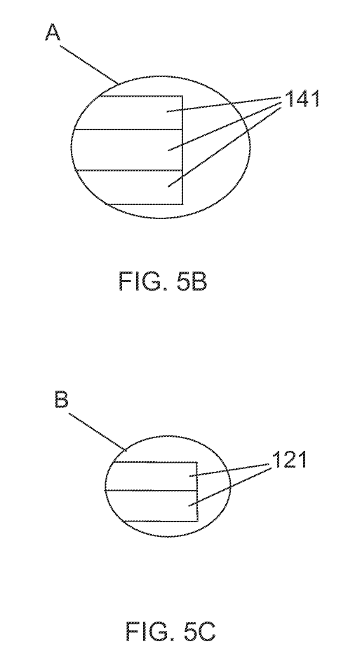

FIG. 5A shows an embodiment of the semiconductor device provided by the present invention. A cross-sectional view of embodiments of the mask structure and the GaN-based layer in circle A and circle B are shown in FIG. 5B and 5C respectively. As shown in the figures, the mask structure 140 may include one mask layer 141 or plural stacked mask layers 141 deposited on the backside 112 of the SiC substrate 110 by physical vapor deposition (PVD). Each of the one or more mask layers 141 can be made of photoresist, Si, SiN, Al, Ni, Ni—P, Ti, TiW, or Au, preferably of Ni or Ni—P. Or the mask structure 140 may includes at least one seed layer 142 and at least one metal mask layer 143 formed on the seed layer on the backside 112 of the SiC substrate 110. Each of the at least one seed layer 142 is made of Ti, TiW, or Au, and each of the at least one metal mask layer 143 is made of Al, Ni, or Ni—P, preferably of Ni or Ni—P. A potassium iodide solution can be used for the wet etching of gold in the step of removing the mask structure and cleaning the inner surface of the via hole when the mask structure 140 comprises gold, which can further reduce the defectivity of byproduct to 0.22%. The GaN-based layer 120 may comprise one epitaxial layer 121 made of GaN, AlGaN, MN, or InGaN, or more than one stacked epitaxial layers, each of which is made of GaN, AlGaN, MN, or InGaN.

The present invention has the following advantages:

1. The descum process performed before the substrate backside etching can effectively remove the surface defects caused by the SiC substrate grinding and thus decrease micromasking on the etching area. The step of substrate backside polishing in a conventional wafer backside processing can be avoided, which results in a lower equipment cost and an improved cycle time.

2. The inner surface of the through wafer via hole is cleaned by using a mixed acid with ultrasonic or acoustic vibrations can effectively remove the byproduct caused by the plasma etching. The byproduct can be significantly decreased and the yield of the through wafer via hole can be significantly improved.

3. The descum process performed before the GaN-based layer etching can effectively remove the surface defects caused by the SiC substrate etching and thus decrease micromasking in the through substrate via hole.

To sum up, the method for forming a through wafer via hole in a semiconductor device provided by the present invention can indeed meet its anticipated objective to provide improved via hole side-wall profiles and smooth surface morphologies with minimal micromasking, and to improve the etch rate. A higher throughput and higher yield can thereby be achieved.

The description referred to in the drawings and stated above is only for the preferred embodiments of the present invention. Many equivalent local variations and modifications can still be made by those skilled at the field related with the present invention and do not depart from the spirit of the present invention, so they should be regarded to fall into the scope defined by the appended claims.

What is claimed is:

1. A method for forming a through wafer via hole in a semiconductor device, comprising steps of:
A1. providing a wafer having a SiC substrate with a front side and a backside and a GaN-based layer formed on the front side of the SiC substrate;
A2. providing a mask structure on the backside of the SiC substrate to define an etching area;
A3. descumming the etching area defined by the mask structure;
A4. forming a through wafer via hole by etching through the SiC substrate and the GaN-based layer in the etching area; and
A5. removing the mask structure and cleaning the backside of the SiC substrate and the inner surface of the through wafer via hole.

2. The method for forming a through wafer via hole in a semiconductor device according to claim 1, wherein the mask structure includes at least one seed layer and at least one metal mask layer formed on the seed layer.

3. The method for forming a through wafer via hole in a semiconductor device according to claim 2, wherein each of the at least one seed layer is made of Ti, TiW, or Au.

4. The method for forming a through wafer via hole in a semiconductor device according to claim 2, wherein each of the at least one metal mask layer is made of Al, Ni, or Ni—P.

5. The method for forming a through wafer via hole in a semiconductor device according to claim 1, wherein the mask structure comprising at least one mask layer, each of which is made of Si, SiN, Al, Ni, Ni—P, Ti, TiW, or Au.

6. The method for forming a through wafer via hole in a semiconductor device according to claim 1, wherein descumming the etching area in step A3 is done by using a plasma comprising one or more of Ar, CF₄, and O₂.

7. The method for forming a through wafer via hole in a semiconductor device according to claim 1, wherein etching the etching area in step A4 is done by using high power fluorine-based plasma, chlorine-based plasma, or fluorine-based and chlorine-based plasma.

8. The method for forming a through wafer via hole in a semiconductor device according to claim 1, wherein removing the mask structure and cleaning the backside of the SiC substrate and the inner surface of the through wafer via hole in step A5 is done by using an acidic solution with ultrasonic or acoustic vibrations.

9. The method for forming a through wafer via hole in a semiconductor device according to claim 8, wherein the acidic solution is a HNO₃ solution, a HCl solution, or a mixed acid consisting of HNO₃ and HCl solution.

10. The method for forming a through wafer via hole in a semiconductor device according to claim 9, wherein the mixed acid is made of HNO₃, HCl, and de-ionized water in a proportion of 1:1:5.

11. The method for forming a through wafer via hole in a semiconductor device according to claim 1, wherein the GaN-based layer comprises at least one epitaxial layer, each of which is made of GaN, AlGaN, MN, or InGaN.

12. A method for forming a through wafer via hole in a semiconductor device, comprising the steps of:
B1. providing a wafer having a SiC substrate with a front side and a backside and a GaN-based layer formed on the front side of the SiC substrate;
B2. providing a mask structure on the backside of the SiC substrate to define an etching area;
B3. descumming the etching area defined by the mask structure;
B4. forming a through substrate via hole by etching the etching area through the SiC substrate to the GaN layer or partially through the GaN layer;
B5. removing the mask structure and cleaning the backside of the SiC substrate and the inner surface of the through substrate via hole;
B6. descumming the inner surface of the through substrate via hole;
B7. forming a through wafer via hole by etching through the GaN layer in the through substrate via hole; and
B8. cleaning the inner surface of the through wafer via hole.

13. The method for forming a through wafer via hole in a semiconductor device according to claim 12, wherein the mask structure includes at least one seed layer and at least one metal mask layer formed on the seed layer.

14. The method for forming a through wafer via hole in a semiconductor device according to claim 13, wherein each of the at least one seed layer is made of Ti, TiW, or Au.

15. The method for forming a through wafer via hole in a semiconductor device according to claim 13, wherein each of the at least one metal mask layer is made of Al, Ni, or Ni—P.

16. The method for forming a through wafer via hole in a semiconductor device according to claim 12, wherein the mask structure comprising at least one mask layer, each of which is made of Si, SiN, Al, Ni, Ni—P, Ti, TiW, or Au.

17. The method for forming a through wafer via hole in a semiconductor device according to claim 12, wherein descumming the etching area in step B3 is done by using a plasma comprising one or more of Ar, CF₄, and O₂.

18. The method for forming a through wafer via hole in a semiconductor device according to claim 12, wherein etching the etching area in step B4 is done by using high power fluorine-based plasma.

19. The method for forming a through wafer via hole in a semiconductor device according to claim 12, wherein removing the mask structure and cleaning the backside of the SiC substrate and the inner surface of the through wafer via hole in step B5 is done by using an acidic solution with ultrasonic or acoustic vibrations.

20. The method for forming a through wafer via hole in a semiconductor device according to claim 19, wherein the acidic solution is a HNO₃ solution, a HCl solution, or a mixed acid consisting of HNO₃ and HCl solution.

21. The method for forming a through wafer via hole in a semiconductor device according to claim 20, wherein the mixed acid is made of HNO₃, HCl, and de-ionized water in a proportion of 1:1:5.

22. The method for forming a through wafer via hole in a semiconductor device according to claim 12, wherein descumming the inner surface of the through substrate via hole in step B6 is done by using a plasma comprising Ar.

23. The method for forming a through wafer via hole in a semiconductor device according to claim 12, wherein the step of etching through the GaN layer in step B7 uses chlorine-based plasma.

24. The method for forming a through wafer via hole in a semiconductor device according to claim 23, wherein the chlorine-based plasma comprises Cl₂, Ar, and He.

25. The method for forming a through wafer via hole in a semiconductor device according to claim 12, wherein the GaN-based layer comprises at least one epitaxial layer, each of which is made of GaN, AlGaN, MN, or InGaN.
